(19) United States
(12) Patent Application Publication
(10) Pub. No.: US 2005/0227482 A1
(43) Pub. Date: Oct. 13, 2005

(54) Composition useful for removal of bottom anti-reflection coatings from patterned ion-implanted photoresist wafers

(76) Inventors: Michael B. Korzenski, Danbury, CT (US); Thomas H. Baum, New Fairfield, CT (US)

Correspondence Address: ATMI, INC., 7 COMMERCE DRIVE, DANBURY, CT, 06810, US

(21) Appl. No.: 10/807,858

(22) Filed: Mar. 24, 2004

(51) Int. Cl. H01L 21/4763; H01L 21/44

(52) U.S. Cl. 438/639

(57) ABSTRACT

A method and composition for removing a bottom anti-reflection coating (BARC) layer from semiconductor substrates having such BARC layers is described. The removal composition includes a supercritical fluid, a co-solvent, an etchant and a surfactant. Such removal compositions overcome the intrinsic deficiency of SCCO₂ as a removal reagent, viz., the non-polar character of SCCO₂ and its associated inability to solubilize species such as inorganic salts and polar organic compounds that must be removed from the semiconductor substrate.

### FIELD OF THE INVENTION

The present invention relates to supercritical fluid-based compositions useful in semiconductor manufacturing for the removal of organic and inorganic bottom anti-reflection coatings (BARCs) from substrates having such BARC layers thereon, and to methods of using such compositions for removal of BARC layers from semiconductor substrates.

### DESCRIPTION OF THE RELATED ART

In the microelectronics industry, the process of miniaturization entails shrinking the size of individual semiconductor devices and crowding more of the devices within a given unit area. With miniaturization, problems arise such as proper electrical isolation between components. One methodology used to form structures that electrically isolate conductive materials from each other on a semiconductor substrate is photolithography. However, attempts to isolate components from each other are constrained by current photolithographic limits of about 0.25 microns.

Photolithography techniques comprise the steps of coating, exposure, and development. A wafer is coated with a positive or negative photoresist substance and subsequently covered with a mask that defines patterns to be retained or removed in subsequent processes. Following the proper positioning of the mask, the mask has directed therethrough a beam of monochromatic radiation, such as ultraviolet (UV) light or deep UV (DUV) light (≈250 nm), to make the exposed photoresist material more or less soluble in a selected rinsing solution. The soluble photoresist material is then removed, or “developed,” thereby leaving behind a pattern identical to the mask.

Currently, there are four developed wavelengths of radiation used in the photolithographic industry—436 nm, 365 nm, 248 nm, and 193nm—and recent efforts have focused on 157 nm lithography processes. In theory, with each wavelength decrease, smaller features can be created on the semiconductor chip. However, because the reflectively of the semiconductor substrate is inversely proportional to the photolithographic wavelength, interference and unevenly exposed photoresist has limited the consistency of the critical dimensions of the semiconductor device.

For example, upon exposure to DUV radiation, it is well known that the transmissivity of photoresist combined with the high reflectivity of the substrates to the DUV wavelengths results in the reflection of the DUV radiation back into the photoresist thereby producing standing waves in the photoresist layer. The standing waves trigger further photochemical reactions in the photoresist causing an uneven exposure of the photoresist, including in masked portions not intended to be exposed to the radiation, which results in variations in linewidths, spacing and other critical dimensions.

In order to address the transmissivity and reflectivity problems, bottom anti-reflective coatings (BARCs), both inorganic and organic in nature, have been developed which are applied to substrates prior to applying the photoresist. As the photoresist is exposed to DUV radiation, the BARC absorbs a substantial amount of the DUV radiation, thereby preventing radiation reflection and standing waves.

For example, organic BARCs, including, but not limited to, polysulfones, polyureas, polyurea sulfones, polyacrylates and poly(vinyl pyridine), are typically 600-1200 Å thick and deposited using spin-on coating techniques. Typically, organic BARCs are planarizing layers, filling up the vias evenly, because the polymeric materials used do not readily crosslink. Organic BARCs prevent light reflection by matching the reflective index of the BARC layer with that of the photoresist layer while simultaneously absorbing radiation thereby preventing further penetration to the deeper interfaces.

In contrast, inorganic BARCs, including silicon oxynitrides (SiOₓN_{y}), are deposited using CVD deposition techniques and as such, conformal coverage of the substrate is achieved with good uniform thickness of the BARC layer. Inorganic BARCs reduce transmissivity and reflectivity by destructive interference wherein the light reflected from the BARC-photoresist interface cancels out the light reflected from the BARC-substrate interface.

Removal of BARC materials has proven to be difficult and/or costly. If not removed, the BARC layer may interfere with subsequent silicidation or contact formation. Because organic BARCs are typically planarizing layers, overetching of the BARC is needed for complete removal of the organic BARC layer from the wafer surface. Alternatively, U.S. Pat. No. 6,669,995 issued to Insalaco et al., describes a method wherein at least a portion of the organic BARC is removed by exposing the coating to a dosage of UV radiation in the 200 nm-320 nm range. Conventional processes for the removal of inorganic BARCs include dry etching, such as oxygen-plasma etching using additives such as argon, helium, hydrogen bromide or carbon tetrafluoride.

Supercritical fluids (SCF) provide an alternative method for removing BARC layers from the semiconductor surface. SCFs diffuse rapidly, have low viscosity, near zero surface tension, and can penetrate easily into deep trenches and vias. Further, because of their low viscosity, SCFs can rapidly transport dissolved species. However, SCFs are highly non-polar and as such, many species are not adequately solubilized therein.

It would therefore be a significant advance in the art to provide a supercritical fluid-based composition that overcomes the deficiencies of the prior art relating to the removal of BARC layers from semiconductor substrates.

### SUMMARY OF THE INVENTION

The present invention relates to supercritical fluid-based compositions useful in semiconductor manufacturing for the removal of bottom anti-reflection coatings (BARCs) layers from substrates having same thereon, and to methods of using such compositions for removal of BARC layers from semiconductor substrates.

In one aspect, the invention relates to a bottom anti-reflection coating (BARC) removal composition, comprising at least one SCF, at least one co-solvent, at least one etchant and at least one surfactant.

In another aspect, the invention relates to a bottom anti-reflection coating (BARC) removal composition, comprising supercritical carbon dioxide (SCCO₂), triethylamine trihydrofluoride, a fluorosurfactant and isopropyl alcohol.

In yet another aspect, the invention relates to a method of removing a bottom anti-reflection coating (BARC) layer from a substrate having same thereon, said method comprising contacting the substrate having the BARC layer thereon with an SCF-based removal composition comprising at least one SCF, at least one co-solvent, at least one etchant, and at least one surfactant, for sufficient time and under sufficient contacting conditions to at least partially remove the BARC layer from the substrate.

In a further aspect, the invention relates to a method of removing an ion implanted photoresist layer and a bottom anti-reflection coating (BARC) layer from a substrate having same thereon, said method comprising contacting the substrate having the photoresist layer and the BARC layer thereon with a SCF-based removal composition comprising at least one SCF, at least one co-solvent, at least one etchant, and at least one surfactant, for sufficient time and under sufficient contacting conditions to at least partially remove the photoresist layer and the BARC layer from the substrate.

Other aspects, features and embodiments of the invention will be more fully apparent from the ensuing disclosure and appended claims.

### BRIEF DESCRIPTION OF THE DRAWINGS

FIG. 1 is a scanning electron microscope (SEM) image at 50 k magnification of a cross-section of the control wafer showing the 70 nm BARC layer sandwiched between the silicon substrate and the photoresist layer.

FIG. 2 is an optical image of a plan view of the sample in FIG. 1.

FIG. 3 is an optical image of the wafer of FIG. 2, processed using a SCCO₂/fluoride/fluorinated surfactant composition, showing removal of the photoresist layer.

FIG. 4 is an optical image of the wafer of FIG. 2, processed using a SCCO₂/fluoride/fluorinated surfactant/methanol composition, showing removal of the photoresist layer and the BARC layer.

### DETAILED DESCRIPTION OF THE INVENTION, AND PREFERRED EMBODIMENTS THEREOF

The present invention is based on the discovery of a supercritical carbon fluid-based composition that is highly efficacious for the removal of photoresist and bottom anti-reflection coatings (BARCs) layers from patterned semiconductor wafers on which same are present. Specifically, the present invention relates to the removal of photoresist and BARC layers from patterned ion implanted semiconductor wafers.

Because of its readily manufactured character and its lack of toxicity and negligible environmental effects, supercritical carbon dioxide (SCCO₂) is a preferred SCF in the broad practice of the present invention, although the invention may be practiced with any suitable SCF species, with the choice of a particular SCF depending on the specific application involved. Other preferred SCF species useful in the practice of the invention include oxygen, argon, krypton, xenon, and ammonia. Specific reference to SCCO₂ hereinafter in the broad description of the invention is meant to provide an illustrative example of the present invention and is not meant to limit the same in any way.

SCCO₂ is often regarded as an attractive reagent for removal of unwanted layers from the surface of a semiconductor wafer, since SCCO₂ has the characteristics of both a liquid and a gas. Like a gas, it diffuses rapidly, has low viscosity, near-zero surface tension, and penetrates easily into deep trenches and vias. Like a liquid, it has bulk flow capability as a “wash” medium.

Despite these ostensible advantages, however, supercritical CO₂ is non-polar. Accordingly, it will not solubilize many species, including the inorganic BARCs, e.g., SiOₓN_{y}, or polar organic BARC compounds, e.g., polysulfones and polyureas, that must be removed from the semiconductor substrate prior to subsequent processing. The non-polar character of SCCO₂ thus poses an impediment to the use of such reagent for complete and efficient BARC removal.

The present invention, however, is based on the discovery that disadvantages associated with the non-polarity of SCCO₂ and other SCFs can be overcome by appropriate formulation of SCCO₂-based removal compositions with additives as hereinafter more fully described, and the accompanying discovery that removing photoresist and BARC layers from a substrate with a SCCO₂-based removal medium is highly effective and achieves damage-free, residue-free removal of the photoresist and BARC layers from the substrate, e.g., a patterned ion implanted semiconductor wafer, having same thereon.

In one aspect, the invention relates to SCCO₂-based removal compositions useful in removing photoresist and/or BARC layers from a semiconductor substrate. The formulation of the present invention comprises SCCO₂, at least one co-solvent, at least one etchant, and at least one surfactant, present in the following ranges, based on the total weight of the composition:

| component of | % by weight |
|---|---|
| SCCO₂ | about 60.0% to about 90.0% |
| co-solvent | about 10.0% to about 30.0% |
| etchant | about 0.01% to about 5.0% |
| surfactant | about 0.01% to about 5.0% |

In the broad practice of the invention, the SCCO₂-based removal composition may comprise, consist of, or consist essentially of SCCO₂, at least one co-solvent, at least one etchant and at least one surfactant. In general, the specific proportions and amounts of SCCO₂, co-solvent, etchant, and surfactant, in relation to each other may be suitably varied to provide the desired removal action of the SCCO₂-based composition for the photoresist and/or BARC layer species and/or processing equipment, as readily determinable within the skill of the art without undue effort.

The inclusion of the co-solvent with SCCO₂ serves to increase the solubility of the composition for photoresist and/or BARC constituent species, e.g., SiOₓN_{y}, polysulfones and polyureas. The co-solvent used in the SCCO₂-based removal composition can be an alkanol or an amine, or a combination thereof. In one embodiment of the invention, the co-solvent includes a straight-chain or branched C₁-C₆ alkanol (i.e., methanol, ethanol, isopropanol, etc.), or a mixture of two or more of such alcohol species. In another embodiment of the invention, the co-solvent is an amine including, but not limited to, monoethanolamine, triethanolamine, triethylenediamine, methyldiethanolamine, pentamethyldiethylenetriamine, or a glycol amine such as diglycolamine, N-methylpyrrolidone (NMP), N-octylpyrrolidone, N-phenylpyrrolidone and vinyl pyrrolidone. In a preferred embodiment, the alcohol is isopropanol (IPA).

When the photoresist or BARC layer has been hardened by ion implantation, the ion implanted photoresist is advantageously removed from the substrate using an etchant, including hydrogen peroxide, acids, fluoride ion source compounds, or a combination thereof. The etchant(s) is added to the solution in an effective concentration, as readily determinable within the skill of the art, by the simple expedient of contacting the ion implant hardened photoresist with compositions of varying concentrations of the etchant(s), and determining the corresponding respective removal levels for the photoresist. Preferred acids include nitric acid, acetic acid and sulfuric acid. Preferred fluoride ion sources include hydrofluoric acid (HF), ammonium fluoride (NH₄F) and triethylamine trihydrofluoride ((C₂H₅)₃N.3HF). In a preferred embodiment, the fluoride ion source is triethylamine trihydrofluoride.

The surfactants contemplated in the SCCO₂-based removal composition of the present invention may include nonionic surfactants, such as fluoroalkyl surfactants, ethoxylated fluorosurfactants, polyethylene glycols, polypropylene glycols, polyethylene or polypropylene glycol ethers, carboxylic acid salts, dodecylbenzenesulfonic acid or salts thereof, polyacrylate polymers, dinonylphenyl polyoxyethylene, silicone or modified silicone polymers, acetylenic diols or modified acetylenic diols, and alkylammonium or modified alkylammonium salts, as well as combinations comprising at least one of the foregoing. In a preferred embodiment, the surfactant is an ethoxylated fluorosurfactant such as ZONYL® FSO-100 fluorosurfactant (DuPont Canada Inc., Mississauga, Ontario, Canada).

Alternatively, the surfactants may include anionic surfactants, or a mixture of anionic and non-ionic surfactants. Anionic surfactants contemplated in the SCF-based composition of the present invention include, but are not limited to, fluorosurfactants such as ZONYL® UR and ZONYL® FS-62 (DuPont Canada Inc., Mississauga, Ontario, Canada), sodium alkyl sulfates, ammonium alkyl sulfates, alkyl (C₁₀-C₁₈) carboxylic acid ammonium salts, sodium sulfosuccinates and esters thereof, e.g., dioctyl sodium sulfosuccinate, and alkyl (C₁₀-C₁₈) sulfonic acid sodium salts.

In general, the specific proportions and amounts of SCCO₂, co-solvent, etchant and surfactant in relation to each other may be suitably varied to provide the desired solubilizing (solvating) action of the SCCO₂/co-solvent/etchant/surfactant solution for the specific photoresist and/or BARC layers to be cleaned from the substrate. Such specific proportions and amounts are readily determinable by simple experiment within the skill of the art without undue effort.

The removal efficiency of the SCCO₂/co-solvent/etchant/surfactant composition may be enhanced by use of elevated temperature conditions in the contacting of the photoresist and/or BARC layers to be removed with the SCCO₂-based removal composition.

The SCCO₂-based removal compositions of the invention may optionally be formulated with additional components to further enhance the removal capability of the composition, or to otherwise improve the character of the composition. Accordingly, the composition may be formulated with stabilizers, chelating agents, oxidation inhibitors, complexing agents, etc.

In one embodiment, the SCF-based removal composition of the invention includes SCCO₂, IPA, triethylamine trihydrofluoride, and a fluorosurfactant.

In another aspect, the invention relates to methods of removal of photoresist and/or BARC layers, e.g., SiOₓN_{y}, polysulfones, polyureas, polyurea sulfones, polyacrylates and poly(vinyl pyridine), from a semiconductor wafer surface using the SCCO₂-based removal compositions described herein.

The SCCO₂-based removal compositions of the present invention overcome the disadvantages of the prior art BARC removal techniques by minimizing the volume of chemical reagents needed, thus reducing the quantity of waste, while simultaneously providing a composition and method having recyclable constituents, e.g., the SCFs.

The appropriate SCCO₂-based removal composition can be employed to contact a wafer surface having photoresist and/or BARC layers thereon at a pressure in a range of from about 1500 to about 4500 psi for sufficient time to effect the desired removal of the layers, e.g., for a contacting time in a range of from about 1 minutes to about 20 minutes and a temperature of from about 30° C. to about 100° C., although greater or lesser contacting durations and temperatures may be advantageously employed in the broad practice of the present invention, where warranted. In a preferred embodiment, the contacting temperature is in the range of from about 50° C. to about 90° C., preferably about 70° C.

The effect of specific temperature increases and temperature ranges on the nature and extent of the removal of a specific photoresist and/or BARC layers may be readily empirically determined by varying the temperature and measuring the amount of BARC material removed from the substrate by the SCCO₂-based removal composition at that temperature. In such manner, optimal temperature levels may be determined for a specific SCCO₂-based removal composition of the invention, for the specific material to be removed.

In like manner, the process conditions other than temperature may be selected and optimal or otherwise advantageous conditions determined within the skill of the art, including the superatmospheric pressure at which the supercritical fluid composition is contacted with the photoresist and/or BARC material to be removed from the substrate, the flow and/or static character of the SCCO₂-based removal composition contacting, and the duration of the contacting.

The wafer surface containing the photoresist and/or BARC layer may be processed by dynamically flowing or statically soaking the SCCO₂-based removal composition over the wafer surface containing the photoresist and/or BARC layer.

A “dynamic” contacting mode involves continuous flow of the composition over the wafer surface, thus maximizing the mass transfer gradient and affecting complete removal of the BARC layers from the surface. A “static soak” contacting mode involves contacting the wafer surface with a static volume of the composition, maintaining contact therewith for a continued (soaking) period of time.

The removal process in a particularly preferred embodiment includes sequential processing steps including dynamic flow of the SCCO₂-based removal composition over the wafer surface containing the photoresist and/or BARC layer, followed by a static soak of the wafer in the SCCO₂-based removal composition, with the respective dynamic flow and static soak steps being carried out alternatingly and repetitively, in a cycle of such alternating steps.

For example, the dynamic flow/static soak steps may be carried out for four successive cycles in the aforementioned illustrative embodiment, as including a sequence of 2.5 min-10 min dynamic flow, 2.5 min-5 min high pressure static soak, e.g., about 3000 psi to about 4500 psi, 2.5 min-10 min dynamic flow, and 2.5 min-10 min low pressure static soak, e.g., about 1500 psi to about 2900 psi. In a preferred embodiment, the sequence consists of a 2.5 min dynamic flow, a 2.5 min static soak at 4500 psi, a 2.5 min dynamic flow, and a 2.5 min static soak at 1500 psi.

Following the contacting of the SCCO₂-based removal composition with the wafer surface, the wafer thereafter preferably is washed with copious amounts of SCF/methanol/deionized water solution in a first washing step, to remove any residual precipitated chemical additives from the region of the wafer surface in which particle removal has been effected, and finally with copious amounts of pure SCF, in a second washing step, to remove any residual methanol and/or precipitated chemical additives from the wafer surface. Preferably, the SCF used for washing is SCCO₂.

The co-solvent/etchant/surfactant component of the SCCO₂-based removal compositions of the present invention is readily formulated by simple mixing of ingredients, e.g., in a mixing vessel under gentle agitation.

Once formulated, such SCCO₂-based removal compositions are applied to the wafer surface for contacting with the photoresist and/or BARC layers thereon, at suitable elevated pressures, e.g., in a pressurized contacting chamber to which the SCCO₂-based removal composition is supplied at suitable volumetric rate and amount to effect the desired contacting operation for removal of the organic BARC layer from the wafer surface.

It will be appreciated that specific contacting conditions for the SCCO₂-based removal compositions of the invention are readily determinable within the skill of the art, based on the disclosure herein, and that the specific proportions of ingredients and concentrations of ingredients in the SCCO₂-based removal compositions of the invention may be widely varied while achieving desired removal of the photoresist and/or BARC layer from the wafer surface.

The features and advantages of the invention are more fully shown by the illustrative examples discussed below.

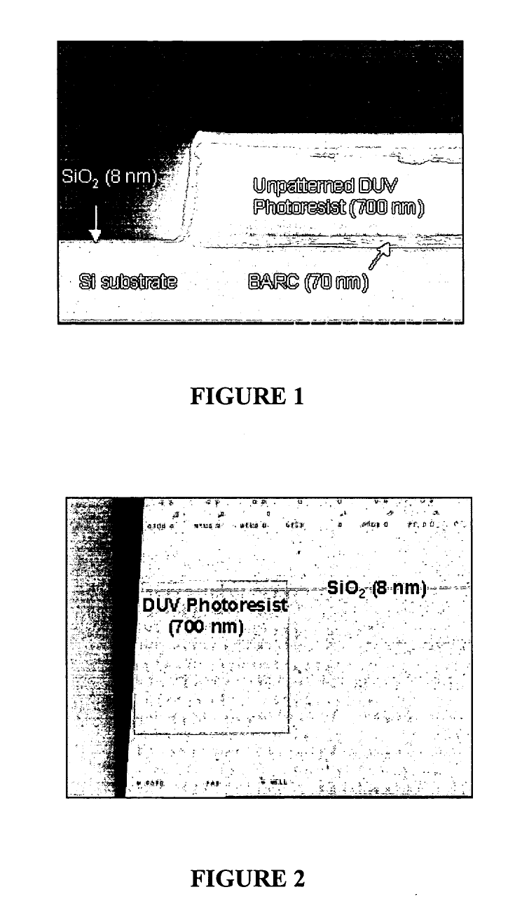

The sample wafers examined in this study were Si/SiO₂ patterned wafers having organic BARC layers and photoresist layers thereon. Various chemical additives, as described herein, were added to the SCCO₂-based removal composition and photoresist and/or organic BARC layer removal efficiency evaluated. The temperature of the SCCO₂-based removal composition was maintained at 70° C. throughout the removal experiments. Following layer removal, the wafers were thoroughly rinsed with copious amounts of SCCO₂/methanol/deionized water and pure SCCO₂ in order to remove any residual solvent and/or precipitated chemical additives. The results are shown in FIGS. 1-4, as described hereinbelow.

FIG. 1 is an scanning electron microscope (SEM) image of a cross-section of the control wafer showing the Si wafer surface having an 8 nm SiO₂ layer, a 70 nm organic BARC layer and a 700 nm deep ultraviolet (DUV) photoresist layer thereon.

FIG. 2 is a plan view optical image of the wafer of FIG. 1.

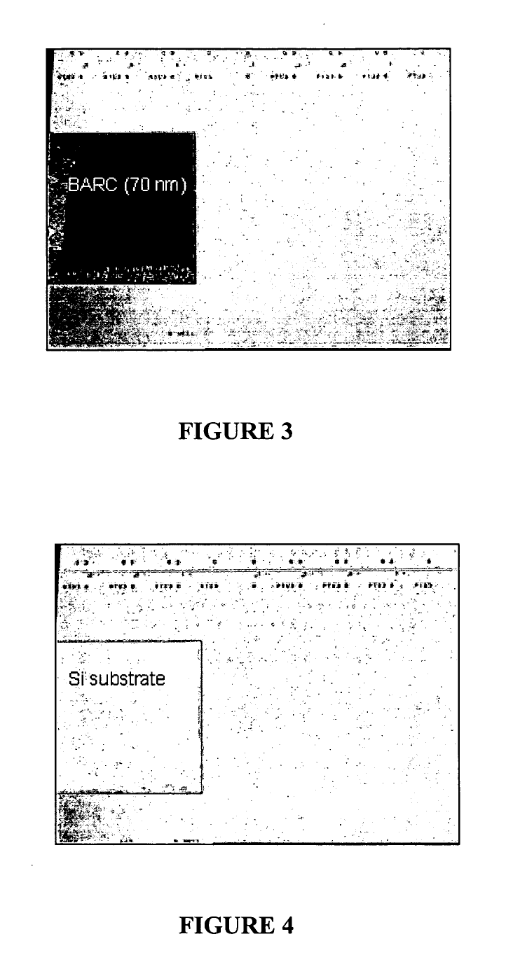

FIG. 3 is an optical image of the wafer of FIG. 2 following processing using a SCCO₂/fluoride-source/fluorinated surfactant composition, showing that although the photoresist was removed from the wafer, the organic BARC layer remains on the Si/SiO₂ wafer surface.

FIG. 4 is an optical image of the wafer of FIG. 2 following processing using a SCCO₂/fluoride-source/fluorinated surfactant/co-solvent composition, showing that both the photoresist and the organic BARC layers have been removed from the Si/SiO₂ wafer surface.

The above-described photographs thus evidence the efficacy of SCCO₂-based removal compositions in accordance with the invention, for removal of photoresist and/or BARC layers from wafer surfaces.

The following formulation resulted in substantial removal of organic BARC layers from the patterned Si/SiO₂ surface. “Substantial removal” is defined as greater than about 98% removal of the BARC layer from the semiconductor device, as determined by optical microscopy. In this specific embodiment, 100% removal of the BARC layer was observed in all areas in 18 minutes at 70° C.

| Component | Weight Percent |
|---|---|
| triethylamine trihydrofluoride | 0.91 |
| ZONYL ® FSO-100 fluorosurfactant | 0.08 |
| isopropyl alcohol | 6.0 |
| SCCO₂ | 73.01 |

Accordingly, while the invention has been described herein in reference to specific aspects, features and illustrative embodiments of the invention, it will be appreciated that the utility of the invention is not thus limited, but rather extends to and encompasses numerous other aspects, features and embodiments. Accordingly, the claims hereafter set forth are intended to be correspondingly broadly construed, as including all such aspects, features and embodiments, within their spirit and scope.

1. A bottom anti-reflection coating (BARC) removal composition, comprising at least one SCF, at least one co-solvent, at least one etchant and at least one surfactant.

2. The BARC removal composition of claim 1, wherein the SCF comprises a fluid selected from the group consisting of carbon dioxide, oxygen, argon, krypton, xenon, and ammonia.

3. The BARC removal composition of claim 1, wherein the SCF comprises carbon dioxide.

4. The BARC removal composition of claim 1, wherein the co-solvent comprises at least one C₁-C₆ alkanol.

5. The BARC removal composition of claim 1, wherein the co-solvent comprises isopropanol.

6. The BARC removal composition of claim 1, wherein the co-solvent comprises an amine selected from the group consisting of monoethanolamine, triethanolamine, triethylenediamine, methyldiethanolamine, pentamethyldiethylenetriamine, diglycolamine, N-methylpyrrolidone (NMP), N-octylpyrrolidone, N-phenylpyrrolidone and vinyl pyrrolidone.

7. The BARC removal composition of claim 1, wherein the etchant comprises at least one of HF, ammonium fluoride, triethylamine trihydrofluoride, hydrogen peroxide, acetic acid, nitric acid and sulfuric acid.

8. The BARC removal composition of claim 1, wherein the etchant comprises triethylamine trihydrofluoride.

9. The BARC removal composition of claim 1, wherein the surfactant comprises at least one nonionic surfactant or at least one anionic surfactant.

10. The BARC removal composition of claim 9, wherein the nonionic surfactant comprises at least one species selected from the group consisting of fluoroalkyl surfactants, ethoxylated fluorosurfactants, polyethylene glycols, polypropylene glycols, polyethylene ethers, polypropylene glycol ethers, carboxylic acid salts, dodecylbenzenesulfonic acid, dodecylbenzenesulfonic salts, polyacrylate polymers, dinonylphenyl polyoxyethylene, silicone polymers, modified silicone polymers, acetylenic diols, modified acetylenic diols, alkylammonium salts, modified alkylammonium salts.

11. The BARC removal composition of claim 9, wherein the surfactant comprises an ethoxylated fluorosurfactant.

12. The BARC removal composition of claim 9, wherein the anionic surfactant comprises at least one species selected from the group consisting of fluorosurfactants, sodium alkyl sulfates, ammonium alkyl sulfates, C₁₀-C₁₈ alkyl carboxylic acid ammonium salts, sodium sulfosuccinates and esters thereof, and C₁₀-C₁₈ alkyl sulfonic acid sodium salts.

13. The BARC removal composition of claim 1, wherein the SCF-based removal composition comprises about 60.0 wt % to about 90.0 wt % SCF, about 10.0 wt % to about 30.0 wt % co-solvent, about 0.01 wt % to about 5.0 wt % etchant, and about 0.01 wt % to about 5.0 wt % surfactant, based on the total weight of the composition.

14. A bottom anti-reflection coating (BARC) removal composition, comprising supercritical carbon dioxide (SCCO₂), triethylamine trihydrofluoride, a fluorosurfactant and isopropyl alcohol.

15. A method of removing a bottom anti-reflection coating (BARC) layer from a substrate having same thereon, said method comprising contacting the substrate having the BARC layer thereon with an SCF-based removal composition comprising at least one SCF, at least one co-solvent, at least one etchant, and at least one surfactant, for sufficient time and under sufficient contacting conditions to at least partially remove the BARC layer from the substrate.

16. The method of claim 15, wherein the SCF comprises a fluid selected from the group consisting of carbon dioxide, oxygen, argon, krypton, xenon, and ammonia.

17. The method of claim 15, wherein the SCF comprises carbon dioxide.

18. The method of claim 15, wherein the contacting conditions comprise pressure in a range of from about 1500 psi to about 4500 psi.

19. The method of claim 15, wherein said contacting time is in a range of from about 1 minutes to about 20 minutes.

20. The method of claim 15, wherein the co-solvent comprises at least one C₁-C₆ alkanol.

21. The method of claim 15, wherein the co-solvent comprises isopropanol (IPA).

22. The method of claim 15, wherein the co-solvent comprises an amine selected from the group consisting of monoethanolamine, triethanolamine, triethylenediamine, methyldiethanolamine, pentamethyldiethylenetriamine, diglycolamine, N-methylpyrrolidone (NMP), N-octylpyrrolidone, N-phenylpyrrolidone and vinyl pyrrolidone.

23. The method of claim 15, wherein the etchant comprises at least one of HF, ammonium fluoride, triethylamine trihydrofluoride, hydrogen peroxide, acetic acid, nitric acid and sulfuric acid.

24. The method of claim 15, wherein the etchant comprises triethylamine trihydrofluoride.

25. The method of claim 15, wherein the surfactant comprises at least one nonionic surfactant or at least one anionic surfactant.

26. The method of claim 25, wherein the surfactant comprises at least one species selected from the group consisting of fluoroalkyl surfactants, ethoxylated fluorosurfactants, polyethylene glycols, polypropylene glycols, polyethylene ethers, polypropylene glycol ethers, carboxylic acid salts, dodecylbenzenesulfonic acid, dodecylbenzenesulfonic salts, polyacrylate polymers, dinonylphenyl polyoxyethylene, silicone polymers, modified silicone polymers, acetylenic diols, modified acetylenic diols, alkylammonium salts, modified alkylammonium salts, and combinations comprising at least one of the foregoing.

27. The method of claim 25, wherein the anionic surfactant comprises at least one species selected from the group consisting of fluorosurfactants, sodium alkyl sulfates, ammonium alkyl sulfates, C₁₀-C₁₈ alkyl carboxylic acid ammonium salts, sodium sulfosuccinates and esters thereof, and C₁₀-C₁₈ alkyl sulfonic acid sodium salts.

28. The method of claim 15, wherein the SCF-based removal composition comprises about 60.0 wt % to about 90.0 wt % SCF, about 10.0 wt % to about 30.0 wt % co-solvent, about 0.01 wt % to about 5.0 wt % etchant, and about 0.01 wt % to about 5.0 wt % surfactant, based on the total weight of the composition.

29. The method of claim 15, wherein the BARC layer comprises an organic BARC layer.

30. The method of claim 15, wherein the BARC layer comprises an inorganic BARC layer.

31. The method of claim 15, wherein the contacting step comprises a cycle including (i) dynamic flow contacting of the SCF-based removal composition with the substrate having the BARC layer thereon, and (ii) static soaking contacting of the SCF-based removal composition with the substrate having the BARC layer thereon.

32. The method of claim 31, wherein said cycle comprises alternatingly and repetitively carrying out dynamic flow contacting (i) and static soaking contacting (ii) of the substrate having the BARC layer thereon.

33. The method of claim 15, further comprising washing the substrate, at a region at which the BARC layer has been removed, with a SCF/methanol/deionized water wash solution in a first washing step, and with a SCF in a second washing step, to remove residual precipitated chemical additives in said first washing step, and to remove residual precipitated chemical additives and/or residual alcohol in said second washing step.

34. The method of claim 33, wherein the SCF comprises SCCO₂.

35. The method of claim 15, wherein the contacting conditions comprise temperature in a range of from about 50° C. to about 90° C.

36. A method of removing an ion implanted photoresist layer and a bottom anti-reflection coating (BARC) layer from a substrate having same thereon, said method comprising contacting the substrate having the photoresist layer and the BARC layer thereon with a SCF-based removal composition comprising at least one SCF, at least one co-solvent, at least one etchant, and at least one surfactant, for sufficient time and under sufficient contacting conditions to at least partially remove the photoresist layer and the BARC layer from the substrate.
